(19) United States
(12) Patent Application Publication
(10) Pub. No.: US 2017/0201231 A1
(43) Pub. Date: Jul. 13, 2017

(54) One-Port Resonator Operating with Surface Acoustic Waves

(71) Applicant: Snaptrack Inc., San Diego, CA (US)

(72) Inventors: Ulrike Rösler, Hebertshausen (DE); Werner Ruile, Muenchen (DE); Andreas Bergmann, Haiming (DE); Veit Meister, Unterhaching (DE)

(21) Appl. No.: 15/315,366

(22) PCT Filed: Jul. 16, 2015
(86) PCT No.: PCT/EP2015/066333

§ 371 Date: Nov. 30, 2016

(30) Foreign Application Priority Data
Aug. 19, 2014 (DE) 10 2014 111 828.6

(51) Int. Cl. H03H 9/25

(52) U.S. Cl. CPC H03H 9/25

(57) ABSTRACT

The present invention relates to a one-port resonator (1) operating with surface acoustic waves, comprising an interdigital transducer (2) having a first busbar (6), a second busbar (7) and electrode fingers (8), wherein in an excitation region (10) of the interdigital transducer (2) the electrode fingers (8) are alternately connected to the first busbar (6) and the second busbar (7) in the longitudinal direction (L), wherein the interdigital transducer (2) comprises a first reversed region (11), in which the electrode fingers (8) are alternately connected to the first busbar (6) and the second busbar (7) in the longitudinal direction (L) and which is directly adjacent to the excitation region (10), and wherein that electrode finger (118) of the first reversed region (11) which is directly adjacent to the excitation region (10) in the longitudinal direction (L) and that electrode finger (118) of the excitation region (10) which is directly adjacent thereto are connected to the same busbar (6, 7).

### Description

One-port resonator operating with surface acoustic waves

The present invention relates to a one-port resonator operating with surface acoustic waves (SAW=surface acoustic wave).

A one-port resonator comprises an interdigital transducer having two busbars arranged on a piezoelectric substrate with intermeshing electrode fingers, usually arranged on a periodic grid. An electrical signal applied to the electrodes of the interdigital transducer excites a surface acoustic wave if the signal frequency corresponds to the period of the finger structure.

The one-port resonator furthermore comprises two reflectors, wherein the interdigital transducer adjoins a respective reflector on both sides. If an electrical signal is applied to the electrodes of the interdigital transducer, then a standing surface acoustic wave forms.

One-port resonators operating with surface acoustic waves are used in particular in the construction of reactance filters. An important characteristic variable of a reactance filter is the insertion loss describing the maximum attenuation of a signal passing through the filter in the passband. If the insertion loss is increased, then the transmission property of the filter deteriorates. Accordingly, an insertion loss that is as low as possible should be striven for.

At the resonant frequency, therefore, the one-port resonator should have an as far as possible δ-function-shaped real part of the admittance in order to be suitable for use in a reactance filter.

It is therefore an object of the present invention to specify an improved one-port resonator operating with surface acoustic waves which has for example a steep admittance profile and accordingly is particularly well suited to use in a reactance filter.

The object is achieved by means of a one-port resonator according to the present claim 1.

A one-port resonator operating with surface acoustic waves is specified, comprising an interdigital transducer having a first busbar, a second busbar and electrode fingers, wherein in an excitation region of the interdigital transducer the electrode fingers are alternately connected to the first busbar and the second busbar in the longitudinal direction, wherein the interdigital transducer comprises a first reversed region, in which the electrode fingers are alternately connected to the first busbar and the second busbar in the longitudinal direction and which is directly adjacent to the excitation region, and wherein that electrode finger of the first reversed region which is directly adjacent to the excitation region in the longitudinal direction and that electrode finger of the excitation region which is directly adjacent thereto are connected to the same busbar.

The term “directly adjacent” can be understood here such that, between two electrode fingers that are directly adjacent to one another, no further electrode finger is arranged. Furthermore, the wording “a region is directly adjacent to a further region” can be understood such that no further region is arranged between the regions.

The longitudinal direction is defined as the direction of propagation of a surface acoustic wave excited in the interdigital transducer. The transverse direction is perpendicular to the longitudinal direction. The electrode fingers extend in the transverse direction.

If an AC voltage is applied to the first and second busbars, then a surface acoustic wave is excited in the excitation region. By virtue of the fact that, upon the transition from the excitation region to the first reversed region, two electrode fingers are connected to the same busbar the electrode fingers in the first reversed region excite a surface acoustic wave having a phase shift relative to the wave excited in the excitation region if an AC voltage is applied to the first and second busbars. The excitation in the first reversed region thus counteracts the excitation in the excitation region.

An ideal one-port resonator should have a δ-function in the real part of the admittance in the frequency domain, and the corresponding Hilbert transform in the imaginary part.

The Fourier transformation of this ideal behavior yields a constant in the time domain. The time domain is finite, however, in any real one-port resonator. A corresponding unweighted, finite transducer thus exhibits a sin(x)/x behavior in the frequency domain instead of the δ-function.

As a result of internal reflections, a reflection function is also impressed on said sin(x)/x behavior, but said reflection function is not changed by the present invention.

The present invention modifies the sin(x)/x behavior in the frequency domain in such a way that the typical secondary maxima are reduced and a better approximation to the ideal behavior (δ-function) is thus obtained.

This modification is achieved by means of an as far as possible sin(x)/x-shaped profile in the time domain, the Fourier transform of which is a rectangle and is thus ideally suitable for reducing the secondary maxima.

A first approximation to said sin(x)/x-shaped profile in the time domain is achieved by means of a first reversed region whose excitation is phase-shifted by 180° relative to the excitation region.

The first reversed region is also designated as “reversed region” because it can be designed as follows: firstly an interdigital transducer in which the excitation region extends over the entire length of the interdigital transducer is taken as a starting point. The electrode fingers of the excitation region are then “reversed” in a part of the excitation region, that is to say that they are connected to the respective other busbar. As a result, the first reversed region is formed from said part of the excitation region.

The one-port resonator furthermore comprises a first reflector and a second reflector, wherein the inter-digital transducer is arranged between the first and second reflectors. The reversed region of the inter-digital transducer can be directly adjacent to the first reflector or directly adjacent to the second reflector. In this context, “directly adjacent” means that, between the first reversed region of the inter-digital transducer and the respective reflector, no further region of the interdigital transducer is arranged in the longitudinal direction.

Accordingly, the first reversed region of the inter-digital transducer can be arranged in an edge region of the interdigital transducer. As a result of the arrangement of the first reversed region directly adjacent to one of the reflectors, an excitation profile can arise which has a sin(x)/x profile, wherein the profile is clipped after one of the secondary lobes, for example after the second secondary lobe. Clipping after the second secondary lobe leads to a very good approximation to the desired sin(x)/x profile, this resulting in a better approximation to the ideal admittance function (6-function) in the frequency domain.

Preferably, the first reversed region comprises at least two electrode fingers. In particular, the first reversed region can comprise at least three electrode fingers. The first reversed region can comprise a number of electrode fingers in the range of 2 to 50, preferably in the range of 3 to 40. In this case, the number of fingers in the first reversed region should be chosen depending on further parameters of the inter-digital transducer, such as, for example, the total number of electrode fingers, their width, connection sequence, their longitudinal position (i.e. the position along the direction of propagation of the acoustic wave) and the aperture (i.e. the length of the active overlap region of the juxtaposed fingers of different electrodes).

Furthermore, the one-port resonator can comprise a second reversed region, in which the electrode fingers are alternately connected to the first busbar and the second busbar in the longitudinal direction and which is directly adjacent to the excitation region, and wherein that electrode finger of the second reversed region which is directly adjacent to the excitation region in the longitudinal direction and that electrode finger of the excitation region which is directly adjacent thereto can be connected to the same busbar. Accordingly, the second reversed region can be arranged in the longitudinal direction on the opposite side of the excitation region relative to the first reversed region. Consequently, a respective reversed region can be adjacent to the excitation region on both sides.

With AC voltage being applied, the second reversed region can also excite a surface acoustic wave that is phase-shifted relative to the surface acoustic wave excited in the excitation region. The second reversed region can thus contribute to a correction of the excitation profile in the longitudinal direction and can thereby ultimately increase the real part of the admittance of the one-port resonator at the resonant frequency.

The first reversed region and the second reversed region can comprise the same number of electrode fingers. Alternatively, the first reversed region can comprise a different number of electrode fingers than the second reversed region. The respectively most expedient choice of the number of electrode fingers for each of the two reversed regions depends here on a multiplicity of parameters that determine the frequency behavior of the one-port resonator.

In particular, the second reversed region can comprise at least two electrode fingers. Furthermore, the second reversed region can comprise at least three electrode fingers in some embodiments. Preferably, the second reversed region comprises a number of between 2 and 50 electrode fingers, preferably between 3 and 40 electrode fingers.

The transfer function of the one-port resonator is also crucially influenced by the fact that the interdigital transducer itself is not reflection-free, but rather also forms a reflector. In particular, each of the electrode fingers can reflect a part of the excited surface acoustic wave in the longitudinal direction and also in a direction opposite to the longitudinal direction.

Furthermore, the one-port resonator can comprise a third reversed region, in which the electrode fingers are alternately connected to the first busbar and the second busbar in the longitudinal direction and which is directly adjacent to the first reversed region, wherein that electrode finger of the third reversed region which is directly adjacent to the first reversed region in the longitudinal direction and that electrode finger of the first reversed region which is directly adjacent thereto are connected to the same busbar.

Accordingly, in the longitudinal direction, there can be adjacent to the excitation region firstly the first reversed region and then the third reversed region, wherein the third reversed region comprises reversed electrode fingers relative to the first reversed region. In this case, the third reversed region forms a correction of the surface acoustic wave excited by the first reversed region. The third reversed region can also comprise at least two electrode fingers. Furthermore, the one-port resonator can comprise as many further reversed regions as desired, which can be respectively adjacent to one another. In this case, the electrode fingers within each reversed region can be alternately connected to the first and second busbars in the longitudinal direction and, furthermore, the directly adjacent electrode fingers of two regions that are directly adjacent to one another can be connected to the same busbar.

As described above, an expedient configuration of the admittance of the one-port resonator is achieved by means of the reversed regions. It is furthermore possible to combine the method of the reversed regions with further methods for forming the admittance.

In particular, the one-port resonator can comprise at least first electrode fingers and second electrode fingers, wherein the width of the first electrode fingers differs from the width of the second electrode fingers. It is known that an expedient admittance of a one-port resonator can be realized by the configuration of the width of electrode fingers. This measure can be combined with the reversal of the regions in order to realize the desired admittance even better.

Alternatively or supplementarily, the one-port resonator can comprise at least a first pair of directly adjacent electrode fingers and a second pair of directly adjacent electrode fingers, wherein the distance between the two electrode fingers of the first pair differs from the distance between the two electrode fingers of the second pair. Accordingly, the positioning of the electrode fingers in the longitudinal direction can deviate from a periodic grid for individual electrode fingers. By this means, too, the admittance can be influenced in a desired manner.

The electrode fingers each have an end connected to one of the busbars and each have a free end respectively adjoining a gap. In the transverse direction, a stub finger can be adjacent to the gap, said stub finger being connected to the respective other busbar and not contributing to the excitation of a surface acoustic wave. The transverse position of the gaps can then vary in each case for the electrode fingers connected to the first busbar and/or for the electrode fingers connected to the second busbar. This leads to a variation in the overlap length of adjacent fingers, which is also referred to as aperture. As a result of this so-called aperture weighting, the excitation profile of the interdigital transducer can be influenced such that an admittance with an even better approximation to the δ-function is obtained.

Furthermore, a metallization ratio of the interdigital transducer can be varied in the longitudinal direction. In this case, the metallization ratio is defined as the ratio between the width of an electrode finger of an interdigital electrode structure and the sum of the width and the distance between successive electrode fingers.

Since the present invention does not relate to the reflection function, the latter can still be realized arbitrarily. Therefore, it is not necessary for all the electrode fingers to be configured as so-called normal fingers, which are at a distance from one another that corresponds to half a wavelength of the resonant frequency. Rather, it is also possible for some of the electrode fingers to be embodied differently. By way of example, the resonator can comprise so-called split fingers, in the case of which the distance between one another corresponds to one quarter of the wavelength and two of which respectively replace a normal finger. These two fingers here can be connected in each case to the same busbar.

In accordance with a further aspect, the present invention relates to a filter structure, wherein resonators are interconnected with one another in a ladder-type structure, wherein at least one of the resonators is one of the above-described one-port resonators comprising at least one reversed region. The filter structure can be a reactance filter.

In this case, the filter structure can comprise a signal path having a signal path input and a signal path output and two basic circuit elements interconnected serially in the signal path. Each of the two basic circuit elements can comprise three resonators and a reactance element. One of the resonators, a so-called series resonator, can be interconnected in the signal path in this case. A second resonator (a first parallel resonator), can be interconnected with an electrode at the signal input of the basic circuit element, while a third resonator (a second parallel resonator), can be interconnected with an electrode at the signal output of the basic circuit element. The respective other electrode of the parallel resonators can be electrically connected to one another via a connecting line. Said connecting line can be connected to ground via the reactance element. Such a basic circuit element in the signal path of the filter circuit acts as a bandpass filter.

The filter structure can thus have a ladder-type-like structure. Filter circuits having a ladder-type structure are constructed from serially interconnected basic elements substantially consisting of a resonator in a “series branch” and a resonator in a “parallel branch”. In this case, the characteristic pass frequency of the series resonator corresponds approximately to the blocking frequency of the parallel resonator. Therefore, such a basic element intrinsically forms a passband filter. The right slope of the attenuation characteristic of the passband is crucially determined by the concrete configuration of the series resonator, while the left slope is crucially determined by the configuration of the parallel resonator. Ladder-type filter circuits composed of such basic elements are well known.

The one-port resonator as described above can then be used as a parallel resonator and/or as a series resonator in such a basic element.

The invention is explained in greater detail below with reference to figures.

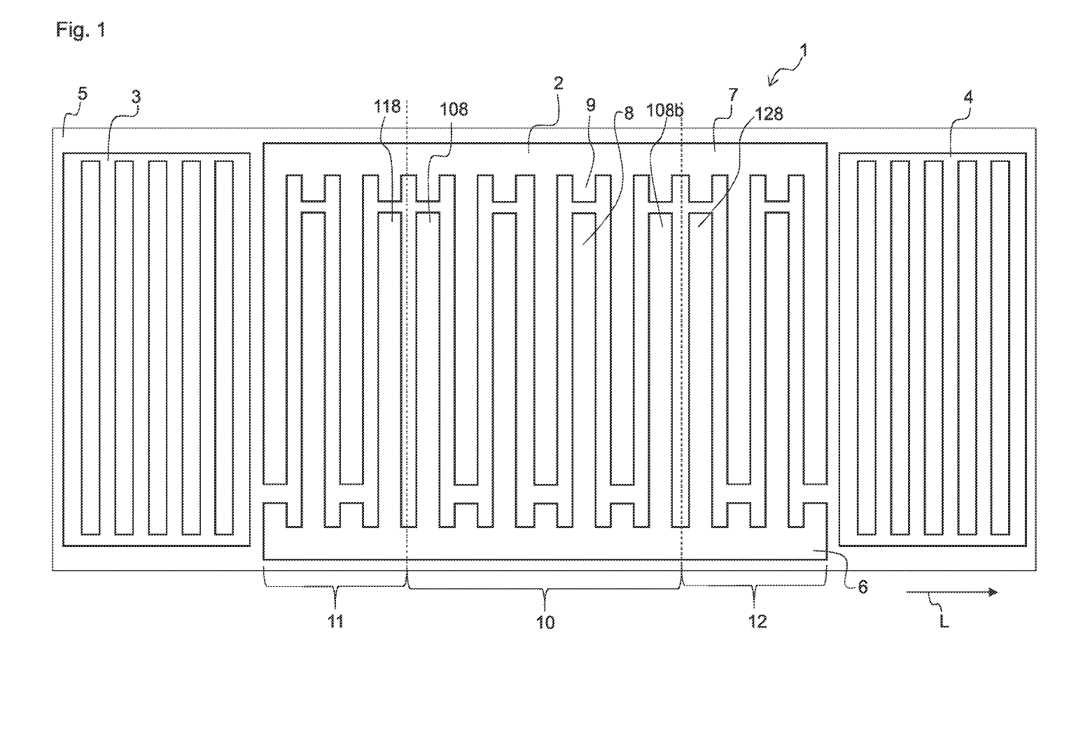

FIG. 1 shows a first exemplary embodiment of a one-port resonator.

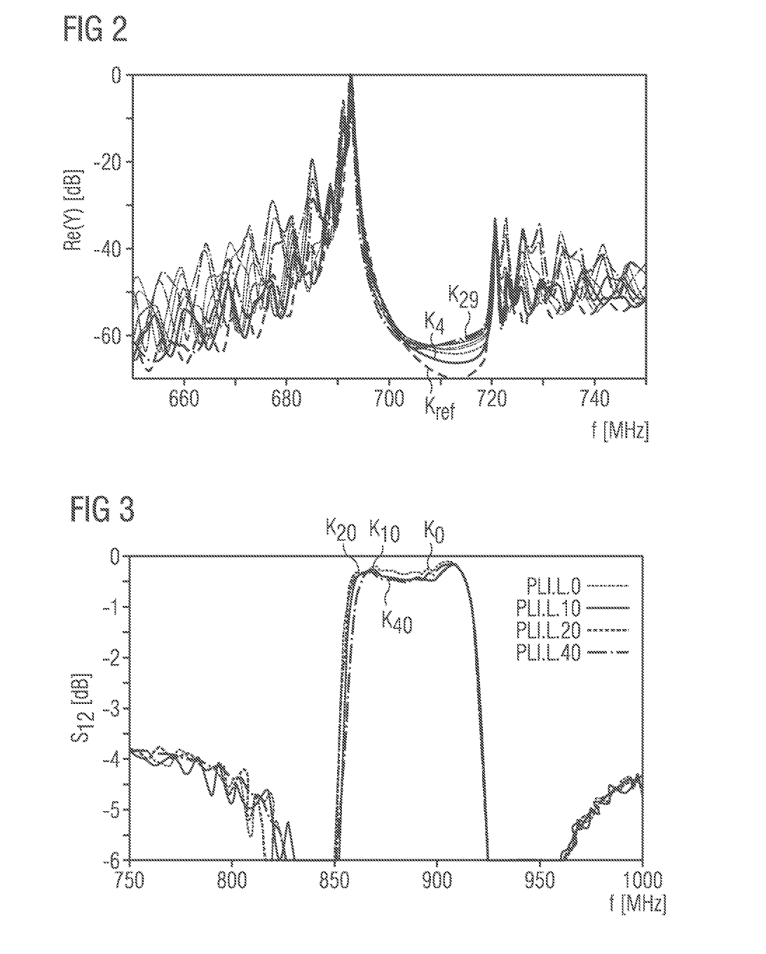

FIG. 2 shows a diagram in which the real part of the admittance for various exemplary embodiments of the one-port resonator is plotted on a logarithmic scale.

FIG. 3 shows an insertion loss of a basic element of a ladder-type structure comprising two one-port resonators.

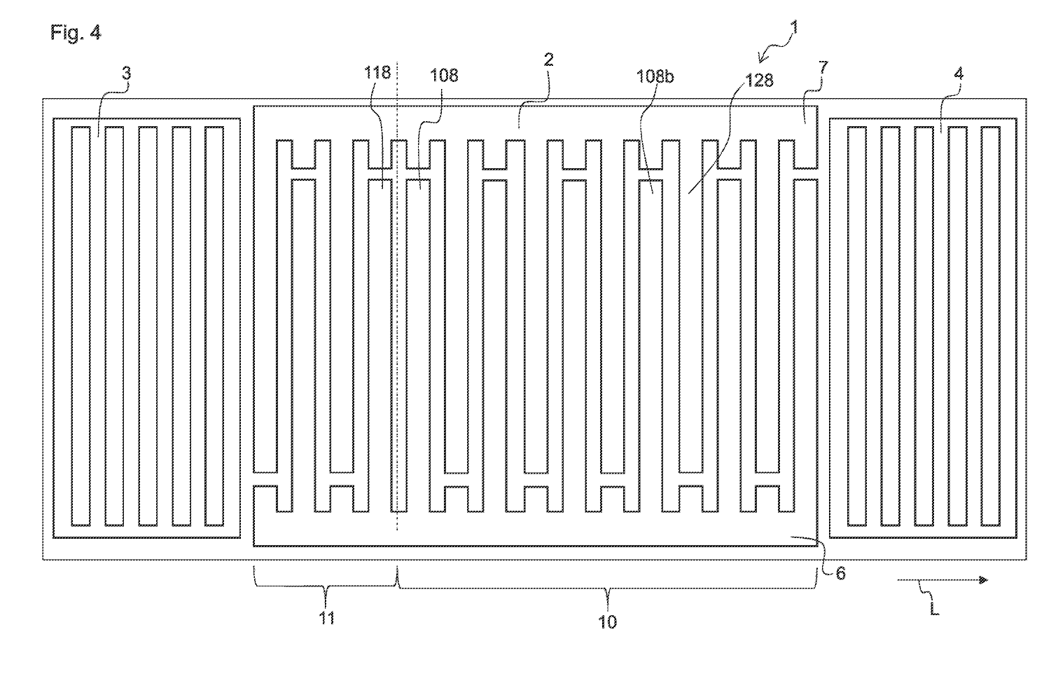

FIG. 4 shows a second exemplary embodiment of the one-port resonator.

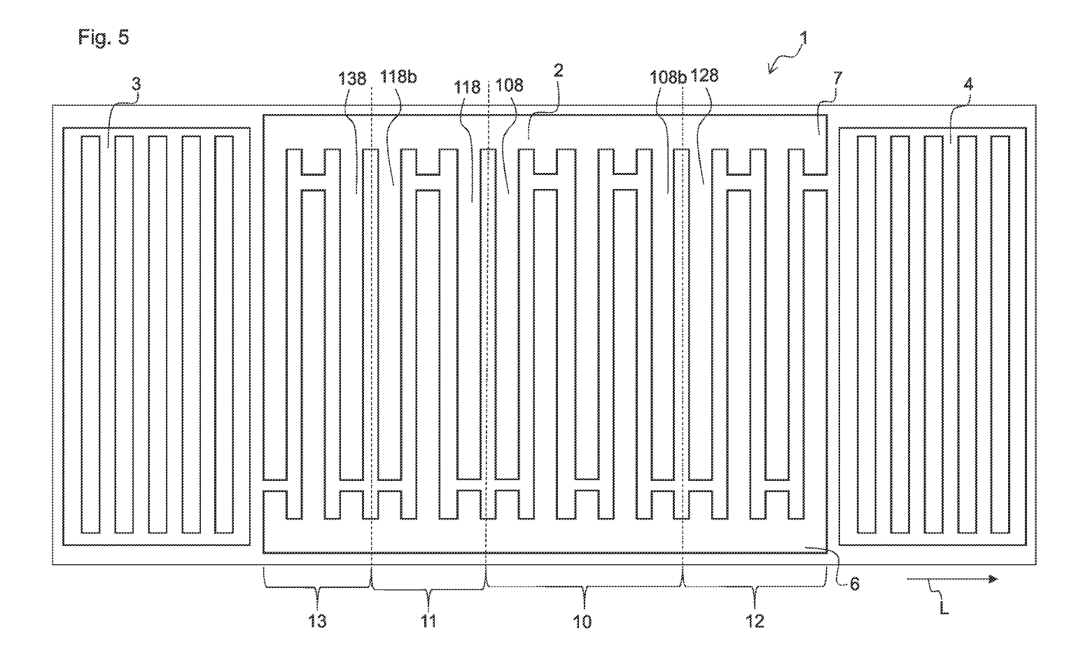

FIG. 5 shows a third exemplary embodiment of a one-port resonator.

The figures here illustrate schematic illustrations which are not true to scale. By way of example, the number of electrode fingers of the interdigital transducers is significantly reduced in the figures, in order to allow a more comprehensible illustration.

FIG. 1 shows a first exemplary embodiment of a one-port resonator 1. The one-port resonator 1 comprises an interdigital transducer 2. Furthermore, the one-port resonator 1 comprises a first reflector 3 and a second reflector 4. The interdigital transducer 2 is arranged between the first reflector 3 and the second reflector in the longitudinal direction L. Furthermore, the one-port resonator 1 comprises a piezoelectric substrate 5, on which the interdigital transducer 2 and the two reflectors 3, 4 are arranged. The piezoelectric substrate 5 can comprise lithium niobate or lithium tantalate, for example.

The interdigital transducer 2 comprises a first busbar 6 and a second busbar 7. Furthermore, the interdigital transducer 2 comprises electrode fingers 8 that serve for exciting a surface acoustic wave. Furthermore, the interdigital transducer 2 comprises stub fingers 9 that do not contribute to the excitation of the acoustic wave. Each of the electrode fingers 8 and of the stub fingers 9 is connected either to the first busbar 6 or to the second busbar 7. In this case, the first busbar 6 and the electrode fingers 8 connected to it form a comb-like structure representing a first electrode of the interdigital transducer 2. Correspondingly, the second busbar 7 and the electrode fingers 8 connected to it form a second comb-like structure, which forms a second electrode of the interdigital transducer 2. The two comb-like structures intermesh.

The interdigital transducer 2 comprises an excitation region 10. In the excitation region 10, the electrode fingers 8 are alternately connected to the first busbar 6 and the second busbar 7. The excitation region 10 is the region of the interdigital transducer 2 having the most electrode fingers 8.

Furthermore, the interdigital transducer 2 comprises a first reversed region 11 and a second reversed region 12. In the longitudinal direction L, firstly the first reversed region 11 is adjacent to the first reflector 3. The excitation region 10 is adjacent to the first reversed region 11. Furthermore the second reversed region 12 is adjacent to the excitation region 10. The second reflector 4 is adjacent to the second reversed region 12.

In each of the first reversed region 11 and the second reversed region 12, the electrode fingers 8 are alternately connected to the first busbar 6 and the second busbar 7 in the longitudinal direction L. In this case, the first reversed region 11 comprises an electrode finger 118 which is directly adjacent to an electrode finger 108 of the excitation region 10 in the longitudinal direction L. These two electrode fingers 108, 118 are connected to the first busbar 6. This has the effect that, upon an AC voltage being applied to the busbars 6, 7, surface acoustic waves that are in each case phase-shifted with respect to one another are excited in the excitation region 10 and in the first reversed region 11. In the first reversed region 11, as it were, a surface acoustic wave is excited which counteracts the surface acoustic wave excited in the excitation region 10 and performs a correction of said wave.

Since, furthermore, the two electrode fingers 108, 118 are connected to the same busbar, no electric field is built up between them upon an AC voltage being applied and, consequently, a piezoelectric excitation does not occur between them either.

In the case of the exemplary embodiment shown in FIG. 1, all the electrode fingers 8 of the inter-digital transducer 2 are at the same distance from one another. In this case, the electrode fingers 8 are arranged on a periodic grid. The distance between the electrode fingers 8 corresponds to half the wavelength of the resonant frequency of the one-port resonator 1.

Furthermore, the electrode finger 108b of the excitation region which is directly adjacent to an electrode finger 128 of the second reversed region 12 in the longitudinal direction L, and said electrode finger 128 of the second reversed region are both connected to the first busbar 6. Accordingly, a surface acoustic wave that is phase-shifted relative to the surface acoustic wave excited in the excitation region 10 is excited in the second reversed region 12 as well. Since, furthermore, the two electrode fingers 108b, 128 are connected to the same busbar, no electric field is, furthermore, built up between them upon an AC voltage being applied and, consequently, a piezoelectric excitation does not occur between them either.

In the exemplary embodiment shown here, the first and second reversed regions 11, 12 comprise the same number of electrode fingers 8.

FIG. 2 shows a diagram that clarifies the effect of the reversed regions 11, 12 on the admittance of the one-port resonator 1. The one-port resonator 1 shown in FIG. 1 is taken as a starting point here, wherein the two reflectors 3, 4 each comprise 50 reflector strips and the interdigital transducer 2 comprises a total of 181 electrode fingers.

FIG. 2 shows a diagram in which a frequency f is plotted on the abscissa axis and the real part of the admittance Re(Y) on a logarithmic scale is furthermore plotted on the ordinate axis. A reference curve K_{ref} is plotted, which shows the admittance for a one-port resonator comprising no reversed regions. The further curves show the admittance for one-port resonators 1 comprising a first and a second reversed region 11, 12, wherein the two reversed regions 11, 12 respectively comprise three, four, five, seven, nine, eleven, 15, 19, 25 and 29 electrode fingers 8. By way of example, the curves which correspond to a one-port resonator 1 comprising two reversed regions 11, 12 comprising respectively four and 29 electrode fingers 8 are marked by K₄ and K₂₉, the index indicating the number of electrode fingers 8 of the reversed regions 11, 12.

It is clearly evident in FIG. 2 that the profile of the admittance near the resonant frequency becomes distinctly steeper in the case of the one-port resonators 1 comprising reversed regions 11, 12. The reversed regions 11, 12 lead to an increase in the real part of the admittance near the resonant frequency.

FIG. 3 shows the insertion loss S₁₂ of a basic element of a ladder-type filter structure. The basic element is constructed from a series resonator and a parallel resonator. What is taken as a starting point here is a series resonator and a parallel resonator which are respectively formed by a one-port resonator 1 comprising an interdigital transducer 2 having 151 electrode fingers 8 and two reflectors 3, 4 each having ten reflector strips.

FIG. 3 illustrates three curves K₁₀, K₂₀ and K₄₀ that respectively illustrate the insertion loss of the basic element for the case where the parallel resonator comprises an excitation region and, adjacent thereto, two reversed regions having respectively ten, 20 or 40 electrode fingers. The curve K₀ is a reference curve illustrating the insertion loss of the basic element for the case where the parallel resonator comprises only the excitation region and no reversed regions.

On the abscissa axis the frequency f is plotted and on the ordinate axis the insertion loss S₁₂ is plotted for the respective basic element of the ladder-type filter structure. It is clearly evident that the lower pass-band slope for the basic elements in which the parallel resonator is formed by a one-port resonator comprising reversed regions turns out to be significantly steeper, given the reference curve K₀ describing a basic element in which the parallel resonator is formed by a one-port resonator without a reversed region.

Accordingly, in particular the use of the one-port resonators according to the invention as a parallel resonator in a ladder-type structure is of interest since the left slope of the insertion loss characteristic is crucially determined by the configuration of the parallel resonator.

FIG. 4 shows a second exemplary embodiment of the one-port resonator 1. The one-port resonator shown in FIG. 4 comprises only a first reversed region 11, which is arranged between the excitation region 10 of the interdigital transducer 2 and the first reflector 3. Furthermore, the excitation region 10 is directly adjacent to the second reflector 4 in the longitudinal direction L.

FIG. 5 shows a third exemplary embodiment of a one-port resonator 1. The one-port resonator 1 shown in FIG. 5 furthermore comprises a third reversed region 13 in addition to the first reversed region 11 and the second reversed region 12. In the longitudinal direction L, there are adjacent to the first reflector 3, in the following order, the third reversed region 13, the first reversed region 11, the excitation region 10, the second reversed region 12 and the second reflector 4. The first, second and third reversed regions 11, 12, 13 each comprises a number of electrode fingers 8 deviating from one another.

An electrode finger 138 of the third reversed region 13 which is directly adjacent to the first reversed region 11 in the longitudinal direction L and that electrode finger 118b of the first reversed region 11 which is directly adjacent thereto are connected in each case to the second busbar 7.

### LIST OF REFERENCE SIGNS

1 One-port resonator

2 Interdigital transducer

3 First reflector

4 Second reflector

5 Piezoelectric substrate

6 First busbar

7 Second busbar

8 Electrode finger

9 Stub finger

10 Excitation region

11 First reversed region

12 Second reversed region

13 Third reversed region

108 Electrode finger of the excitation region

108b Electrode finger of the excitation region

118 Electrode finger of the first reversed region

118b Electrode finger of the first reversed region

128 Electrode finger of the second reversed region

138 Electrode finger of the third reversed region

L Longitudinal direction

1. A one-port resonator (1) operating with surface acoustic waves, comprising
an interdigital transducer (2) having a first busbar (6), a second busbar (7) and electrode fingers (8),
wherein in an excitation region (10) of the interdigital transducer (2) the electrode fingers (8) are alternately connected to the first busbar (6) and the second busbar (7) in the longitudinal direction (L),
wherein the interdigital transducer (2) comprises a first reversed region (11), in which the electrode fingers (8) are alternately connected to the first busbar (6) and the second busbar (7) in the longitudinal direction (L) and which is directly adjacent to the excitation region (10), and
wherein that electrode finger (118) of the first reversed region (11) which is directly adjacent to the excitation region (10) in the longitudinal direction (L) and that electrode finger (118) of the excitation region (10) which is directly adjacent thereto are connected to the same busbar (6, 7).

2-13. (canceled)
